(19) United States
(12) Patent Application Publication
(10) Pub. No.: US 2012/0305956 A1
(43) Pub. Date: Dec. 6, 2012

(54) LED PHOSPHOR PATTERNING

(75) Inventors: Fu-Wen Liu, Hsinchu County (TW); Chyi Shyuan Chern, Taipei (TW); Hsin-Hsien Wu, Hsinchu City (TW); Yung-Chang Chen, Hsinchu City (TW); Ming Shing Lee, Zhudong Township (TW); Tzu-Wen Shih, Xinbei City (TW); Hsin-Hung Chen, Hsinchu City (TW)

(73) Assignee: TAIWAN SEMICONDUCTOR MANUFACTURING COMPANY, LTD., Hsin-Chu (TW)

(21) Appl. No.: 13/150,449

(22) Filed: Jun. 1, 2011

(51) Int. Cl. H01L 33/44

(52) U.S. Cl. 257/98; 438/27; 257/E33.061

(57) ABSTRACT

The present disclosure provides a method of patterning a phosphor layer on a light emitting diode (LED) emitter. The method includes providing at least one LED emitter disposed on a substrate; forming a polymer layer over the at least one LED emitter; providing a mask over the polymer layer and the at least one LED emitter; etching the polymer layer through the mask to expose the at least one LED emitter within a cavity having polymer layer walls; and coating the at least one LED emitter with phosphor.

### TECHNICAL FIELD

The present disclosure relates generally to light emitting diodes, and more particularly, to a phosphor patterning method and apparatus.

### BACKGROUND

A light emitting diode (LED) is a semiconductor material impregnated, or doped, with impurities. These impurities add “electrons” and “holes” to the semiconductor, which can move in the material relatively freely. Depending on the kind of impurity, dopants in a doped region of the semiconductor can have predominantly electrons or holes, and is referred to either as an n-type or p-type semiconductor region, respectively. In LED applications, the semiconductor includes an n-type semiconductor region and a p-type semiconductor region. A reverse electric field is created at the junction between the two regions, which cause the electrons and holes to move away from the junction to form an active region. When a forward voltage sufficient to overcome the reverse electric field is applied across the p-n junction, electrons and holes are forced into the active region and combine. When electrons combine with holes, they fall to lower energy levels and release energy in the form of light.

During operation, a forward voltage is applied across the p-n junction through a pair of electrodes. The electrodes are formed on the semiconductor material with a p-electrode formed on the p-type semiconductor region and an n-electrode formed on the n-type semiconductor region. Each electrode includes a wire bond pad that allows an external voltage to be applied to the LED.

Generally, an LED device includes an LED emitter (or chip or die) that is mounted onto a substrate and encapsulated with an encapsulation material, such as silicone or epoxy. The encapsulation operates to protect the LED emitter and to extract light. LED encapsulation may involve the use of an encapsulation mold having the desired geometric shape which is separately designed and manufactured. The mold is then mounted onto the substrate so that it fits around the LED emitter. The mold is then filled with an encapsulation material which a phosphor may also distributed in. Using such a separately designed and manufactured mold is costly, time consuming, and requires additional manufacturing operations. For example, the mold needs to be designed and fabricated as a separate part, which is time consuming and costly. The mold then needs to be mounted onto the substrate before it can be filled with the encapsulation material, which requires additional manufacturing operations.

Accordingly, what is needed is a LED devices and a method of making the same to address the above issues, with desired morphology to reduce costs and simplify the manufacture of high quality LED devices.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1A illustrates a wafer including a plurality of light emitting diode (LED) emitters in accordance with various embodiments of the present disclosure.

FIGS. 1B-1J show sectional views of a portion of the wafer illustrating a process flow of fabricating an LED apparatus in accordance with various embodiments of the present disclosure.

FIG. 1K is a flowchart illustrating a method of fabricating an LED apparatus in accordance with various aspects of the present disclosure.

FIGS. 2A-1 and 2A-2 illustrate a sectional view and a top view, respectively, of a wafer including a plurality of light emitting diode (LED) emitters in accordance with various embodiments of the present disclosure.

FIGS. 2B-1 through 2H-1 and 2B-2 through 2H-2 illustrate sectional views and top views, respectively, of a process flow of fabricating an LED apparatus in accordance with various embodiments of the present disclosure.

FIG. 3 is a flowchart illustrating a method of fabricating an LED apparatus in accordance with various aspects of the present disclosure.

FIG. 4 illustrates example devices comprising LED assemblies constructed in accordance with embodiments of the present disclosure.

### DETAILED DESCRIPTION

It is understood that the following disclosure provides many different embodiments, or examples, for implementing different features of the disclosure. Specific examples of components and arrangements are described below to simplify the present disclosure. These are, of course, merely examples and are not intended to be limiting. Various features may be arbitrarily drawn in different scales for the sake of simplicity and clarity. It is noted that the same or similar features may be similarly numbered herein for the sake of simplicity and clarity. In addition, some of the drawings may be simplified for clarity. Thus, the drawings may not depict all of the components of a given apparatus (e.g., device) or method.

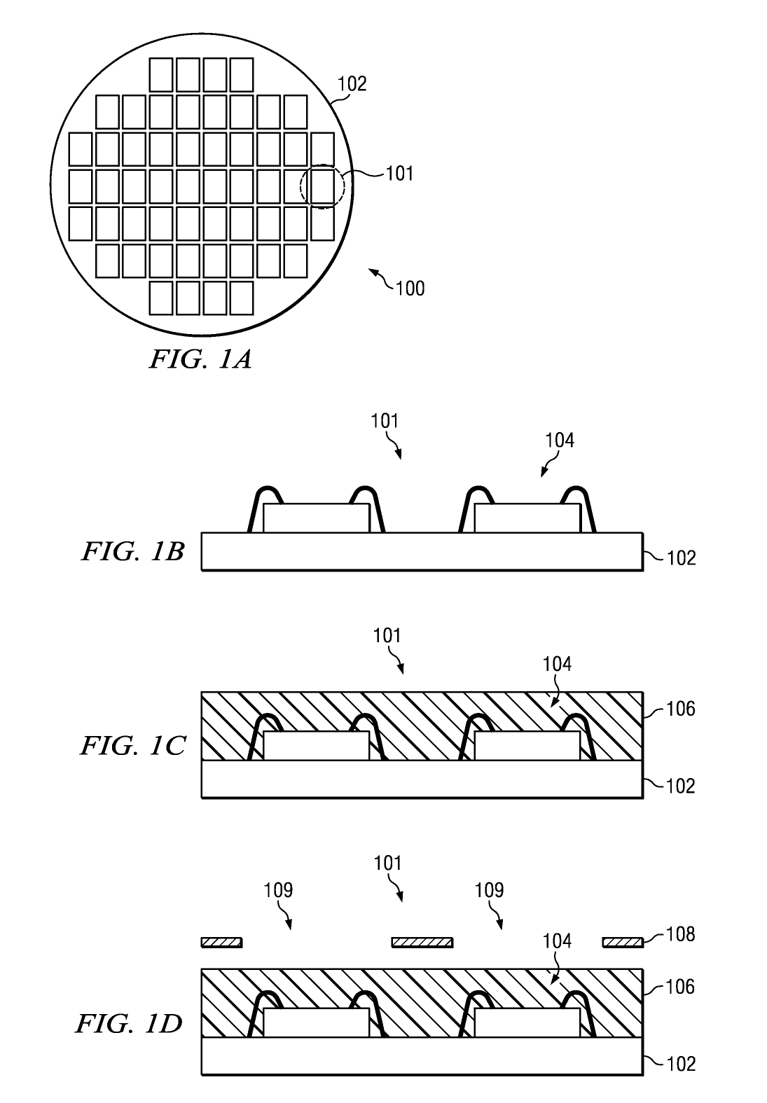

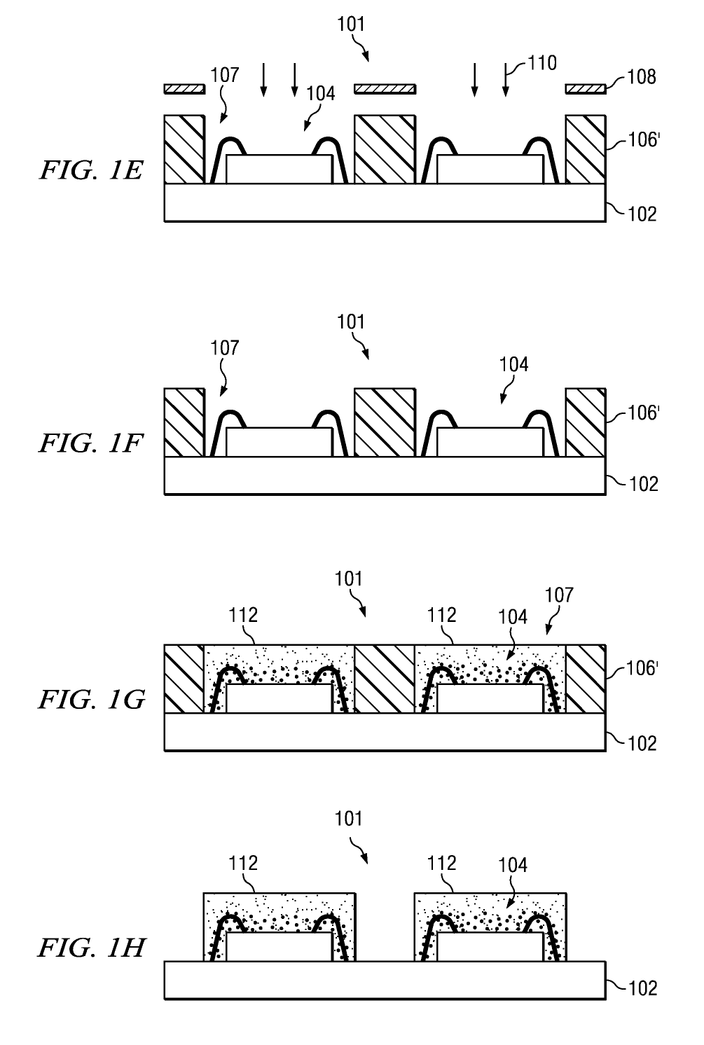

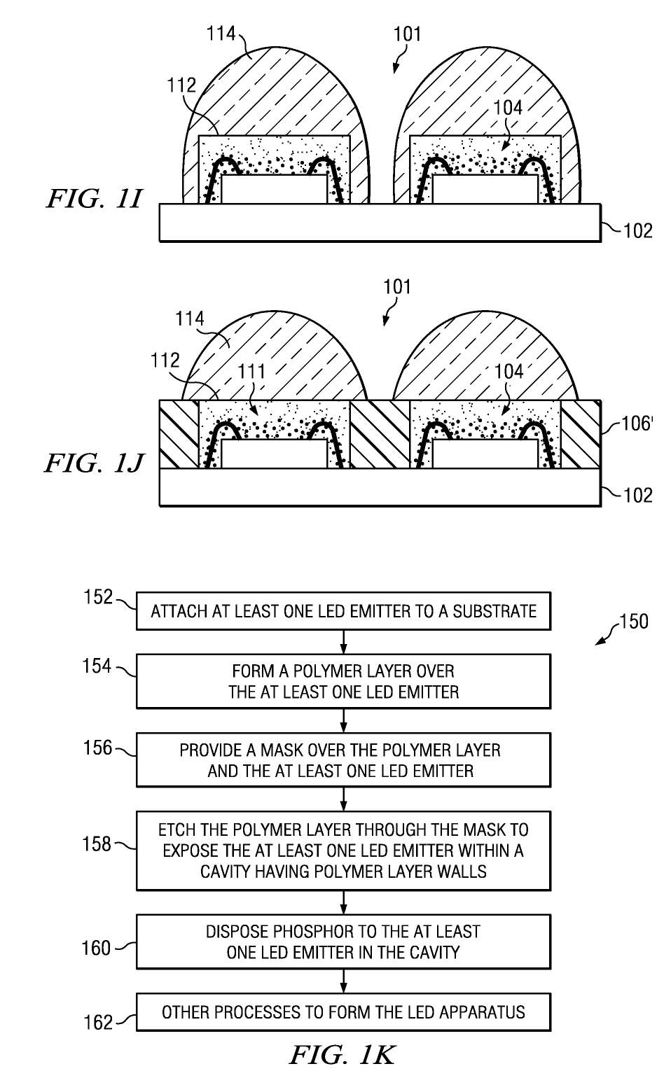

Referring now to FIGS. 1A-1J, FIG. 1A illustrates a wafer or light emitting diode (LED) assembly 100 including a plurality of LED emitters or chips 104 on a substrate 102, and FIGS. 1B-1J show sectional views of a portion 101 of wafer 100 illustrating a process flow of fabricating an LED apparatus having at least one LED emitter 104 in accordance with various embodiments of the present disclosure. It is noted that although a number of LED emitters 104 are shown in FIGS. 1A-1J, the system is suitable for use with one or any number of LED emitters. In one example, LED emitters 104 are die/wire bonded to substrate 102 with a suitable bonding mechanism, such as eutectic bonding or diffusion bonding.

In one example, as shown in FIGS. 1A and 1B, LED assembly 100 comprises a plurality of LED emitters 104 mounted on a substrate 102 that may be ceramic, aluminum or any other suitable substrate material. In one embodiment, substrate 102 may include a silicon substrate, such as a silicon wafer. In the present embodiment, various fabrication steps to the LED assembly is implemented in a wafer level, resulting in a plurality of LED apparatuses. In another embodiment, substrate 102 may include silicon germanium, gallium arsenic, or other suitable semiconductor materials. Alternatively, substrate 102 may include other suitable substrate, such as a metal substrate, a quartz substrate, or a ceramic substrate.

In one embodiment, the substrate 102 further includes metal trace designed and configured for proper bonding effect. In another embodiment, the substrate 102 further includes other features, such as through silicon via (TSV), for electrical wiring. In another embodiment, the substrate may further include various doped regions and other features configured to provide an integrated circuit, such as driving circuit, the LED emitter 104. In furtherance of the embodiment, the substrate 102 includes a doped epitaxy layer, a gradient semiconductor layer, and/or may further include a semiconductor layer overlying another semiconductor layer of a different type such as a silicon layer on a silicon germanium layer. In other examples, a compound semiconductor substrate may include a multilayer silicon structure or a silicon substrate may include a multilayer compound semiconductor structure.

In accordance with an embodiment of the present disclosure, a polymer layer 106 is formed over the LED emitters 104 and onto substrate 102 so that polymer layer 106 surrounds and/or covers the LED emitters 104, as shown in FIG. 1C. Accordingly, in one example, the polymer layer 106 has a thickness greater than a height of the LED emitters 104. In one example, the polymer layer 106 may be clear or an opaque white. In another example, the polymer layer 106 may be comprised of an epoxy or silicone. In yet another example, the polymer layer 106 may be comprised of photoresist, polyimide, polyvinylchloride, polyethylene and/or polypropylene.

In another aspect, the polymer layer may have different optical properties. For example, in an aspect, the polymer layer material comprises a reflective material that reflects light. Thus, light emitted from the LED emitters 104 will be reflected from the polymer material to form a narrower radiation pattern. In another aspect, the polymer material comprises a transparent material that passes light. Thus, light emitted from the LED emitters 104 will pass through the polymer material to form a broader radiation pattern. A more detailed description of how the system provides various radiation patterns is provided in another section of this document. Therefore, in various aspects, different polymer materials can be selected so as to obtain an encapsulation having different radiation patterns if the polymer materials remain in the final LED assembly.

In another embodiment, filler particles are dispersed in the polymer layer 106 to provide desired effect to the emitted light from the LED emitter 104. In another embodiment, the filler particles dispersed in the polymer layer 106 are designed with suitable material, size and concentration for enhanced reflection to the emitted light. In various examples, the filler particles include silver, aluminum, titanium oxide, zirconium oxide or combinations thereof. In another embodiment, the filler particles dispersed in the polymer layer 106 are designed with proper size and concentration to provide a light diffusion mechanism to redistribute the emitted light.

In an aspect, the polymer layer 106 may be deposited onto the substrate 102 by a suitable technique, such as spin-on coating, chemical vapor deposition (CVD), or other suitable processes.

In another aspect, the polymer layer 106 may be deposited by an automated dispenser machine that is programmable and is able to deposit the polymer material onto the substrate 102 in any pattern and/or geometric shape. For example, polymer material may be deposited to form rectangular shapes, circular shapes, curved shapes and/or any combination of shapes that may be selected to define a region in which phosphor and an encapsulation material are to be formed. The polymer material may also be deposited with a desired cross-section.

FIG. 1D illustrates a mask 108 configured over the polymer layer 106 and the LED emitters 104. The mask 108 includes a suitable mask substrate, such as a metal substrate, a ceramic substrate, or a quartz substrate. The mask 108 also includes various openings (or apertures) 109 formed in the mask substrate. Mask 108 may be provided over the polymer layer 106 by various techniques and apparatus. The mask 108 are positioned over the polymer layer 106 such that the apertures 109 of the mask 108 are aligned with respective LED emitters 104. The dimensions of mask 108 (thickness, aperture widths, aperture locations, and the like) are designed and tuned to define polymer dams and the geometry and/or shape of the polymer dams, and accordingly a cavity exposing the LED emitters, thereby controlling the morphology of the eventual encapsulation material and phosphor within the cavity. In one example, the mask 108 is positioned a distance above the polymer layer 106 without direct contact with the polymer layer 106. In an alternative embodiment, the mask 108 directly contacts the polymer layer 106. In furtherance of the embodiment where the mask 108 directly contacts the polymer layer 106, the surface of the polymer layer 106 may be further treated such that the mask 108 can be released without damage to the polymer layer at a later step. For example, a priming process is applied to the polymer layer 106 to form a preparatory coating layer in order to reduce the adhesion between the polymer layer 106 and the mask 108.

FIGS. 1E and 1F illustrate an etch (denoted by arrows 110) of the polymer layer 106 through the apertures of the mask 108 to expose the LED emitters 104 within a respective cavity 107 having polymer layer walls of etched polymer layer 106′. The mask 108 is used as an etch mask during the etching process. The etching process may be a dry etch and/or a wet etch using various suitable chemicals at various suitable etch parameters. In one embodiment, the etching process uses a dry etch with oxygen-based etchant or fluorine-based etchant, such as fluorocarbon. In another embodiment, the etching process uses a wet etch with acid or base etchant. Particularly, the mask 108 is positioned directly on the polymer layer 106 such that the etching process can selectively remove the polymer layer 106 within the apertures of the mask 108.

FIG. 1F shows mask 108 removed and LED emitters 104 within respective cavities 107 formed in etched polymer layer (or patterned polymer layer) 106′. Cavities 107 define a closed region in which phosphor and encapsulation material are to be formed, and in one example is defined by polymer layer walls and a top surface of substrate 102. Although vertical sidewalls are illustrated, the etch of the polymer layer 106 through mask 108 may be easily adjusted to define cavities 107 having tapered sidewalls, rectangular shapes, circular shapes, curved shapes, and/or any combination of shapes that may be selected to define a region in which phosphor and encapsulation material are to be formed. Thus, cavity 107 may be formed to have a desired cross-section. The mask 108 may be reused, such as reused after proper cleaning.

In an alternative embodiment, a reflective material may be alternatively or additionally coated on the sidewalls of the patterned polymer layer 106′ to enhance the reflection of the emitted light from the LED emitter 104. For example, aluminum powder, silver powder, titanium oxide powder or zirconium oxide powder may be coated on the sidewalls of the patterned polymer layer 106′.

FIG. 1G illustrates cavity 107 with phosphor 111 distributed around the LED emitter 104. Additionally, an encapsulation material 112 is disposed to encapsulate the LED emitters 104. Phosphor 111 is an luminescent material that can absorb the emitted light from the LED emitter and emits a light with different wavelength. For example, the phosphor 111 may absorb ultraviolet (UV) light and emits blue light, or absorbs blue light and emits red light. The phosphor 111 may include one or more types of luminescent materials, such as a first one from UV to blue and a second one from blue to red. The phosphor 111 is used to change the spectrum of the emitted light for proper illumination effect, such as white illumination. The phosphor 111 is usually in powder, and may be embedded in the encapsulation material 112. In various examples, the encapsulation material 112 includes silicone, epoxy or other suitable material. In one embodiment, the encapsulation material 112 dispersed with the phosphor 111 is disposed on the LED emitter 104 by a suitable technique, such as spraying or injection. In another embodiment, the encapsulation material 112 includes a first encapsulation layer disposed on the LED emitter and a second encapsulation layer disposed on the first encapsulation layer. The phosphor 111 is either dispersed in the first encapsulation layer or dispersed in the second encapsulation layer. In yet another embodiment, the encapsulation material 112 may include multiple layers such that the phosphor 111 can be configured in one or more of the encapsulation layers for desired illumination effect. As one example, the first luminescent material from UV to blue is dispersed in an encapsulation layer adjacent the LED emitter. The second luminescent material from blue to red is dispersed in another encapsulation layer remote the LED emitter. Alternatively, the phosphor 111 is directly disposed on the LED emitter and the encapsulation material 112 is disposed on the phosphor 111 to encapsulate the LED emitter 104 and the phosphor 111 as well.

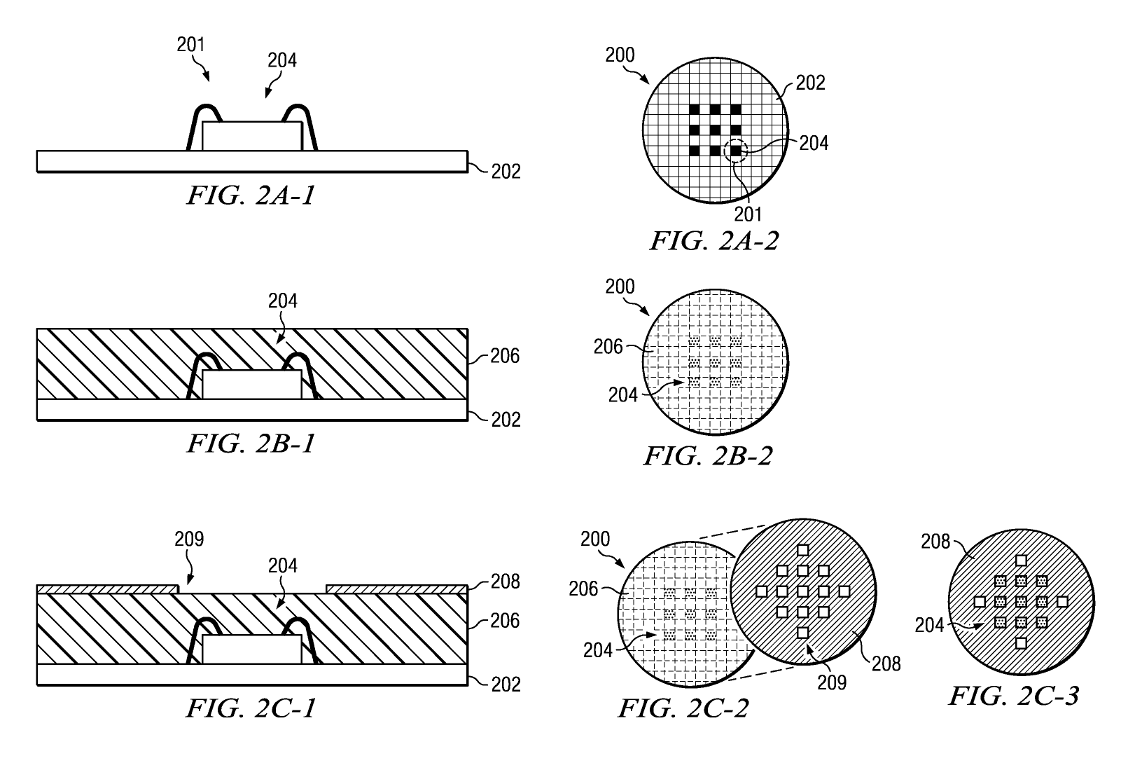

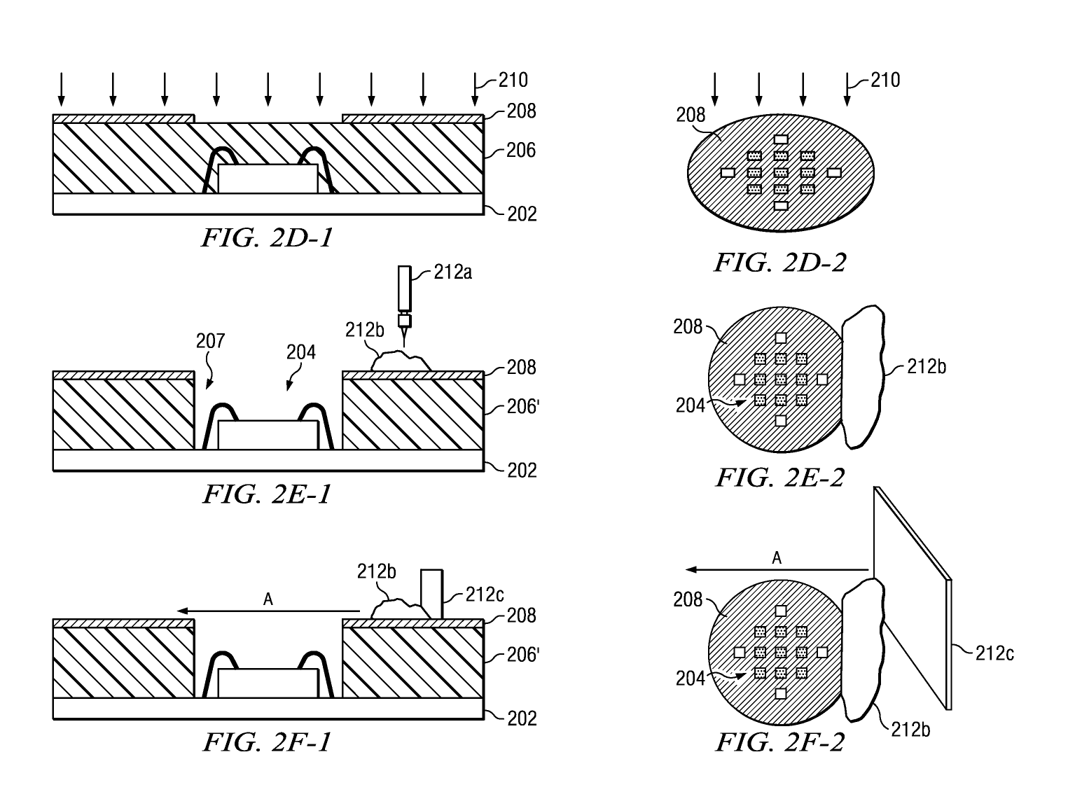

In various embodiments, the encapsulation material 112 may be formed within cavities 107 by other techniques such as dispensing or printing. For example, the encapsulation material 112 dispersed with the phosphor 111 may be deposited by an automated dispenser machine that is programmable and is able to deposit the phosphor material onto the substrate 102 in any pattern and/or geometric shape. In another example, phosphor patterning by screen printing is shown and described below with respect to FIGS. 2A-1 through 2H-1 and 2A-2 through 2H-2. In this case, the mask 108 remain over the patterned polymer layer 106′ and is additionally used as the screen printing mask. In other embodiments, the encapsulation material may be either clear or dispersed with phosphor, or any other encapsulation material that is applied, deposited, or otherwise disposed within the cavities 107 of the patterned polymer layer 106′. Thus, as cavity 107 may be formed to have a desired cross-section, the morphology, form factor, or shape of encapsulation 112 may be easily controlled or defined. Other process may follow, such as polishing or grinding, to form a planarized surface.

FIG. 1H illustrates the removal of the etched polymer layer 106′. FIG. 1I illustrates the formation of a lens 114 over the phosphor encapsulation 112. The lens 114 is aligned with the LED emitter for redistributing the emitted light for desired illumination effect. In one embodiment, the lens 114 includes silicone or epoxy. The lens 114 is formed by a suitable technique, such as molding. In another embodiment, the lens 114, the phosphor 111 and the encapsulation material 112 may be formed in a collective procedure. For example, the phosphor is dispersed in the encapsulation material 112, then the encapsulation material 112 is disposed on the LED emitter 104 and is further shaped to have a curved surface for lens effect.

However, in an alternative embodiment, the patterned polymer layer 106′ remains to be a permanent feature of the LED apparatus or assembly as illustrated in FIG. 1G. In the depicted embodiment, the removal of the patterned polymer layer 106′ is skipped. The lens 114 is formed on the encapsulation material 112 and the patterned polymer 106′, and is aligned with the LED emitter 104, as illustrated in FIG. 1J. As the patterned polymer layer 106′ is either filled with the filler particles or coated with a suitable reflective material layer, the patterned polymer layer 106′ can help to improve the illumination effect of the emitted light from the LED 104 during the operations.

Although various features and steps are described according to various aspects in one or more embodiments, other alternatives may present without departure from the scope of the present disclosure. For example, the LED assembly 100 is further diced to form various LED apparatuses. Thus, the disclosed method provides a wafer level packaging such that the manufacturing cost is reduced and the quality of the products is enhanced.

FIG. 1K is a flowchart 150 illustrating the method for making an LED apparatus. At block 152, the method 150 includes attaching at least one LED emitter to a substrate, such as die/wire bonding the at least one LED emitter to the substrate.

At block 154, the method 150 further includes forming a polymer layer over the at least one LED emitter. In one example, forming the polymer layer includes forming one of a photoresist layer, a polyimide layer, a polyvinylchloride layer, a polyethylene layer, or a polypropylene layer.

At block 156, the method 150 further includes providing a mask over the polymer layer and the at least one LED emitter. The mask includes a mask substrate of metal, quartz or ceramics and further includes various openings formed on the mask substrate.

At block 158, the method 150 further includes etching the polymer layer through the mask to expose the at least one LED emitter within a cavity having polymer layer walls.

At block 160, the method 150 further includes disposing phosphor with encapsulation material to the at least one LED emitter. The disposing phosphor may be implemented according to various embodiments described previously. After disposing the phosphor, other process may follow, such as polishing or grinding, to planarize the surface. The method may further include a etching process to remove the etched polymer after the disposing phosphor.

The method 150 may proceed to step 162 by making various other features and/or implementing other manufacturing process to form one or more LED apparatuses. In one example, a lens is formed such that it is aligned with the LED emitter. In another example, the method 150 may further include a dicing process to separate various LED apparatus by dicing the substrate.

Referring now to FIGS. 2A-1 through 2H-1 and 2A-2 through 2H-2, sectional views and top views, respectively, are illustrated to show a process flow of packaging an LED emitter in accordance with various embodiments of the present disclosure. FIGS. 2A-2 through 2H-2 illustrate a wafer or light emitting diode (LED) assembly 200 including a plurality of LED emitters or chips 204 on a substrate 202, and FIGS. 2A-1 through 2H-1 show sectional views of a portion 201 of wafer 200 illustrating a process flow of encapsulating an LED emitter 204 in accordance with various embodiments of the present disclosure. It is noted that although a number of LED emitters 204 are shown in the figures, one or any number of LED emitters may be utilized and encapsulated. In one example, LED emitters 204 are die/wire bonded to substrate 202.

In one example, as shown in the FIGS. 2A-1 and 2A-2, LED assembly 200 comprises a plurality of LED emitters 204 mounted on a substrate 202 that is similar to the substrate 102 in FIG. 1A and may be ceramic, aluminum or any other suitable substrate material. In one embodiment, substrate 202 may include a semiconductor substrate, and may be comprised of silicon, or alternatively may include silicon germanium, gallium arsenic, or other suitable semiconductor materials. The substrate may further include doped active regions and other features to provide a circuit to be coupled with the LED emitter for driving, control or other functions.

In accordance with an embodiment of the present disclosure, a polymer layer 206 is formed over the LED emitter 204 and onto substrate 202 so that polymer layer 206 surrounds and/or covers the LED emitter 204, as shown in FIGS. 2B-1 and 2B-2. Accordingly, in one example, the polymer layer 206 has a thickness greater than a height of the LED emitter 204. In one example, the polymer layer 206 includes a photo-sensitive material or radiation-sensitive material, such as photoresist. The photoresist can be formed by spin-on coating and may with additional baking according one or more examples.

In another example, the polymer layer 206 may be comprised of an epoxy or silicone. In yet another example, the polymer layer 206 may be comprised of a photoresist, a polyimide, a polyvinylchloride, polyethylene and/or a polypropylene. In an aspect, filler particles like titanium dioxide can be added to the polymer layer 206. In another aspect, the polymer layer 206 may have different optical properties similar to the polymer layer 106 in FIG. 1C. In an aspect, the polymer layer 206 may be deposited over LED emitter 204 and onto the substrate 202 by any one of various deposition techniques and apparatus, such as by spin-on coating, CVD, or other suitable processes. In another aspect, the polymer layer 206 may be deposited by an automated dispenser machine that is programmable and is able to deposit the polymer material onto the substrate 202 in any pattern and/or geometric shape. For example, polymer material may be deposited to form rectangular shapes, circular shapes, curved shapes and/or any combination of shapes that may be selected to define a region in which an encapsulation is to be formed. The polymer material may also be deposited with a desired cross-section.

FIGS. 2C-1 and 2C-2 through 2C-3 illustrate a mask 208 disposed over the polymer layer 206 and the LED emitter 204. Apertures 209 in the mask 208 are aligned with respective LED emitters 204. The mask 208 includes a mask substrate, such as a metal substrate or a ceramic substrate. The mask 208 further includes various apertures 209 formed in the mask substrate. The dimensions of mask 208 (thickness, aperture widths, aperture locations, and the like) may be easily adjusted to define polymer dams and the geometry and/or shape of the polymer dams, and accordingly a cavity exposing the LED emitters, thereby controlling the morphology of the eventual encapsulation formed within the cavity.

FIGS. 2D-1 and 2D-2 illustrate patterning (denoted by arrows 210) of the polymer layer 206 through the mask 208 to expose the LED emitters 204 within a respective cavity 207 having polymer layer walls of patterned polymer layer 206′ (FIGS. 2E-1 and 2E-2).

In one embodiment, the polymer layer 206 includes a photoresist layer and the patterning of the polymer layer 206 includes a lithography procedure. In the present embodiment, the mask 208 serves as a photomask during the lithography procedure. Particularly, the lithography procedure includes radiation exposure and developing. In the radiation exposure, a radiation beam is projected on the mask 208, passes through the aperture 209 of the mask 208, and directed to the photoresist layer within the aperture 209 of the mask 208. In the developing step, the exposed photoresist layer is further developed by applying a suitable developing solution such that the exposed portion of the photoresist layer (positive photoresist) is removed or the unexposed portion of the photoresist layer (negative photoresist) is removed. Other steps may be implemented to form the patterned photoresist layer. For example, a post exposure baking step may be executed before the developing step. One or more baking steps may be implemented after the developing to remove the moisture from the patterned photoresist layer.

In another embodiment, the polymer layer 206 is patterned by etching. In this embodiment, the mask 208 is used as an etch mask during the respective etching process. The etch may be a dry etch and/or a wet etch using various suitable chemicals at various suitable etch parameters. The etching process may be similar to the etching process 110 of FIG. 1E. In the embodiment, the mask 208 may alternatively include other suitable material, such as fused quartz or other glass.

FIGS. 2E-1 and 2E-2 show mask 208 and LED emitters 204 within respective cavities 207 formed in etched polymer layer 206′. Cavities 207 define a closed region in which a phosphor gel is to be formed, and in one example is defined by polymer layer walls and a top surface of substrate 202. FIGS. 2E-1 and 2E-2 further illustrate the dispensing of the phosphor gel 212b onto mask 208 by a dispenser 212a, such as a syringe dispenser. The phosphor gel includes a gel or gel-like material with phosphor embedded in. In one example, the phosphor gel includes silicone or epoxy with phosphor dispersed in.

FIGS. 2F-1 and 2F-2 then show an applicator 212c, such as a squeegee blade which is used to move the phosphor gel in a direction shown by arrow A to move the dispensed phosphor gel into cavities 207, using mask 208 as a screen printing plate. Advantageously, in accordance with one embodiment, mask 208 is not removed yet during this process but is used both as a mask to pattern polymer layer 206, and as a screen printing plate to dispose the phosphor gel in cavity 207. Advantageously, only one reusable mask for both patterning (lithography or etching) and screen printing is used, allowing for reduced costs and higher accuracy as the mask does not need to be re-aligned. Furthermore, a mechanical stamp is not required to release the mold for the phosphor gel.

FIGS. 2G-1 and 2G-2 illustrate cavity 207 disposed or filled with the phosphor gel 212d to encapsulate the LED emitters 204.

FIGS. 2H-1 and 2H-2 1 illustrate the removal of mask 208 and the patterned polymer layer 206′. However, in other embodiments, polymer layer 206′ may remain to be a permanent layer of the LED apparatus or assembly. The phosphor gel may be further cured by a thermal process.

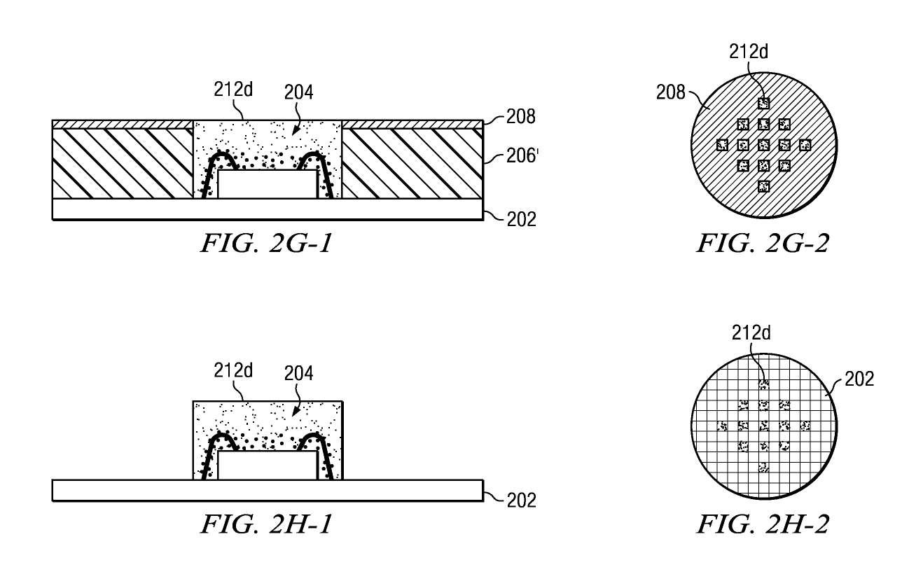

Referring now to FIG. 3, a flowchart illustrates a method 300 for encapsulating an LED emitter in accordance with aspects of the present disclosure. For clarity, the method 300 is described below with reference to FIGS. 1A-1I and 2A-1 through 2H-2.

At block 302, the method 300 includes providing at least one LED emitter disposed on a substrate. In one example, providing the at least one LED emitter disposed on the substrate includes die/wire bonding the at least one LED emitter to the substrate.

At block 304, the method 300 further includes forming a polymer layer over the at least one LED emitter. In one example, forming the polymer layer includes forming one of a photoresist layer, a polyimide layer, a polyvinylchloride layer, a polyethylene layer or a polypropylene layer.

At block 306, the method 300 further includes providing a mask over the polymer layer and the at least one LED emitter.

At block 308, the method 300 further includes patterning the polymer layer through the mask to expose the at least one LED emitter within a cavity having polymer layer walls. The patterning of the polymer layer includes a lithography process (e.g. exposure and developing) to the polymer layer of photoresist using the mask as a photomask, or alternatively an etching process to the polymer layer using the mask as an etch mask.

At block 310, the method 300 further includes disposing with phosphor gel to encapsulate the at least one LED emitter. In one example, disposing phosphor gel includes dispensing phosphor gel over the mask, and filling the cavity with the dispensed phosphor gel using the mask as a screen printing plate. In another example, dispensing the phosphor gel includes using a squeegee blade to move the phosphor gel into the cavity through the mask.

It should be noted that the operations of the method 300 may be rearranged or otherwise modified within the scope of the various aspects. It is further noted that additional processes may be provided before, during, and after the method 300 of FIG. 3, and that some other processes may only be briefly described herein. Thus, other implementations are possible with the scope of the various aspects described herein. curing the phosphor gel within the cavity; For example, the method 300 may further include removing the mask and removing the etched polymer layer. In another example, the method 300 may further include removing the mask, removing the patterned polymer layer, and forming a lens over the encapsulated LED emitter.

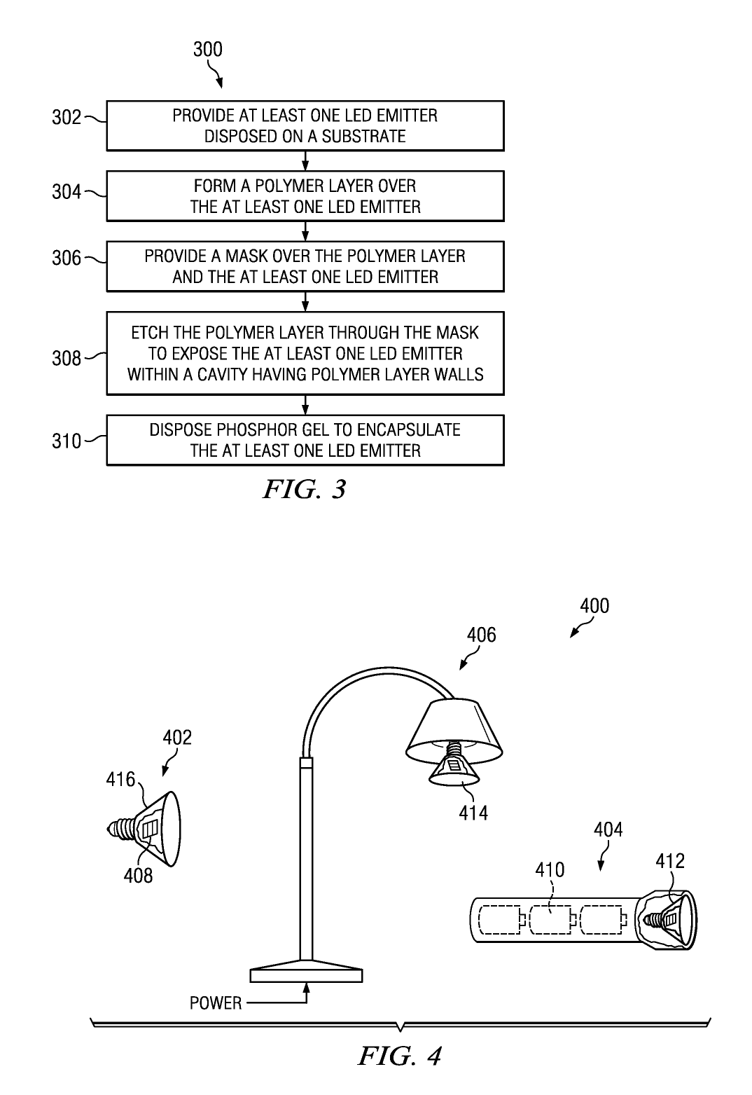

Referring now to FIG. 4, example devices 400 are illustrated, comprising LED assemblies having encapsulations (such as phosphor gel) formed in accordance with aspects of the present disclosure. The devices 400 comprise a lamp 402, an illumination device 404, and a street light 406. Each of the devices shown in FIG. 4 includes an LED assembly having an encapsulation formed by a (phosphor gel or phosphor) deposition system as described herein. For example, the lamp 402 comprises a package 416 and an LED assembly having an encapsulation formed by a phosphor deposition system. The lamp 402 may be used for any type of general illumination. For example, the lamp 402 may be used in an automobile headlamp, street light, overhead light, or in any other general illumination application. The illumination device 404 comprises a power source 410 that is electrically coupled to a lamp 412, which may be configured as the lamp 402. In an aspect, the power source 410 may be batteries or any other suitable type of power source, such as a solar cell. The street light 406 comprises a power source connected to a lamp 414, which may be configured as the lamp 402. In an aspect, the lamp 414 comprises an LED assembly having an encapsulation formed by a phosphor deposition system.

It should be noted that aspects of the phosphor deposition system described herein are suitable for use to form encapsulations for use with virtually any type of LED assembly, which in turn may be used in any type of illumination device and are not limited to the devices shown in FIG. 4.

The various aspects of this disclosure are provided to enable one of ordinary skill in the art to practice the present disclosure. Various modifications to aspects presented throughout this disclosure will be readily apparent to those skilled in the art, and the concepts disclosed herein may be extended to other applications. Thus, the claims are not intended to be limited to the various aspects of this disclosure, but are to be accorded the full scope consistent with the language of the claims. All structural and functional equivalents to the elements of the various aspects described throughout this disclosure that are known or later come to be known to those of ordinary skill in the art are expressly incorporated herein by reference and are intended to be encompassed by the claims.

Moreover, nothing disclosed herein is intended to be dedicated to the public regardless of whether such disclosure is explicitly recited in the claims. No claim element is to be construed under the provisions of 35 U.S.C. .sctn.112, sixth paragraph, unless the element is expressly recited using the phrase “means for” or, in the case of a method claim, the element is recited using the phrase “step for”.

Accordingly, while aspects of a phosphor deposition system have been illustrated and described herein, it will be appreciated that various changes can be made to the aspects without departing from their spirit or essential characteristics. Therefore, the disclosures and descriptions herein are intended to be illustrative, but not limiting, of the scope of the disclosure, which is set forth in the following claims.

Thus, the present disclosure provides method of patterning a phosphor layer on a light emitting diode (LED) emitter. The method includes providing at least one LED emitter disposed on a substrate; forming a polymer layer over the at least one LED emitter; providing a mask over the polymer layer and the at least one LED emitter; etching the polymer layer through the mask to expose the at least one LED emitter within a cavity having polymer layer walls; and coating the at least one LED emitter with phosphor.

In one embodiment, providing the at least one LED emitter disposed on the substrate includes die/wire bonding the at least one LED emitter to the substrate. In another embodiment, forming the polymer layer includes forming one of a photoresist layer, a polyimide layer, a polyvinylchloride layer, a polyethylene layer, and a polypropylene layer. Coating the at least one LED emitter with phosphor may include dispensing a phosphor gel over the mask; and coating the at least one LED emitter with the phosphor gel using the mask as a screen printing plate, wherein the phosphor gel includes an encapsulation material dispersed with the phosphor. Coating the at least one LED emitter with phosphor may include using a squeegee blade to move the phosphor gel into the cavity through the mask. The method may further include curing the phosphor gel within the cavity; and removing the mask. In various examples, the method may further include removing the etched polymer layer, and/or forming a lens over the phosphor and the LED emitter.

In another embodiment, coating the at least one LED emitter with phosphor includes removing the mask; and thereafter dispensing an encapsulation material over the LED emitter, wherein the encapsulation material includes one selected from the group consisting of silicone and epoxy. Coating the at least one LED emitter with phosphor may include dispensing the phosphor around the at least one LED emitter; and dispensing the encapsulation material over the phosphor. Coating the at least one LED emitter with phosphor may include dispensing the encapsulation material dispersed with the phosphor around the at least one LED emitter. In another example, coating the at least one LED emitter with phosphor includes dispensing a first encapsulation layer around the at least one LED emitter; and dispensing a second encapsulation layer over the first encapsulation layer, wherein the first and second encapsulation layers include the encapsulation material, and one of the first and second encapsulation layers further includes the phosphor dispersed therein. The mask includes a mask substrate of a material selected from the group consisting of metal, quartz and ceramic and openings defined in the mask substrate.

The present disclosure also provides another embodiment of a method. The method includes die/wire bonding a plurality of LED emitters on a substrate; forming a photoresist layer over the plurality of LED emitters; providing a mask over the photoresist layer, the mask having an aperture over each of the plurality of LED emitters; performing a lithography exposure to the photoresist layer through the mask; developing the photoresist layer to expose each of the plurality of LED emitters within a respective cavity having photoresist layer walls; and coating each of the plurality of LED emitters in each cavity with phosphor.

In one example, coating each of the plurality of LED emitters in each cavity with phosphor includes dispensing a phosphor gel over the mask; and coating each of the plurality of LED emitters with dispensed phosphor gel using the mask as a screen printing plate. The mask may include one of metal and ceramics. Coating each of the plurality of LED emitters may include using a squeegee blade to move the phosphor gel into each cavity through the mask. The method may further includes curing the phosphor gel; removing the mask; and removing the photoresist layer. 18. The method of claim 17, further comprising dicing the substrate.

The present disclosure also provides a light emitting diode (LED) apparatus. The LED apparatus includes an LED emitter bonded on a substrate; a phosphor distributed on the LED emitter; and a polymeric wall disposed on the substrate and configured to surround the LED emitter and the phosphor, wherein the polymeric wall includes a polymeric material dispersed with filler particles.

In various examples, the polymeric material may include a material selected from the group consisting of polyimide, polyvinylchloride, polyethylene, and polypropylene. The filler particles may include one of silver, aluminum, titanium oxide and zirconium oxide. In one embodiment, the LED apparatus further includes an encapsulation material disposed on the LED emitter, wherein the encapsulation material includes one of silicone and epoxy. The phosphor may be disposed on the LED emitter and covered by the encapsulation material. In another embodiment, the encapsulation material includes a first encapsulation layer on the LED emitter and a second encapsulation layer on the first encapsulation layer; and the phosphor is dispersed in one of the first and second encapsulation layers. The LED apparatus may further includes a lens configured on the first and second encapsulation layers LED emitter.

Advantageously, the present disclosure provides for phosphor encapsulations which can be formed quickly, with flexibility, with repeatability and reproducibility, with desired morphology, and with high yield to reduce costs and simplify the manufacture of LED devices with high quality optical performance.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of patterning a phosphor layer on a light emitting diode (LED) emitter, the method comprising:
providing at least one LED emitter disposed on a substrate;
forming a polymer layer over the at least one LED emitter;
providing a mask over the polymer layer and the at least one LED emitter;
etching the polymer layer through the mask to expose the at least one LED emitter within a cavity having polymer layer walls; and
coating the at least one LED emitter with phosphor.

2. The method of claim 1, wherein providing the at least one LED emitter disposed on the substrate includes die/wire bonding the at least one LED emitter to the substrate.

3. The method of claim 1, wherein forming the polymer layer includes forming one of a photoresist layer, a polyimide layer, a polyvinylchloride layer, a polyethylene layer, and a polypropylene layer.

4. The method of claim 1, wherein coating the at least one LED emitter with phosphor includes:
dispensing a phosphor gel over the mask; and
coating the at least one LED emitter with the phosphor gel using the mask as a screen printing plate,
wherein the phosphor gel includes an encapsulation material dispersed with the phosphor.

5. The method of claim 4, wherein coating the at least one LED emitter with phosphor includes using a squeegee blade to move the phosphor gel into the cavity through the mask.

6. The method of claim 4, further comprising:
curing the phosphor gel within the cavity; and
removing the mask.

7. The method of claim 1, further comprising removing the etched polymer layer.

8. The method of claim 1, further comprising forming a lens over the phosphor and the LED emitter.

9. The method of claim 1, wherein coating the at least one LED emitter with phosphor includes:
removing the mask; and
thereafter dispensing an encapsulation material over the LED emitter, wherein the encapsulation material includes one selected from the group consisting of silicone and epoxy.

10. The method of claim 9, wherein coating the at least one LED emitter with phosphor includes:
dispensing the phosphor around the at least one LED emitter; and
dispensing the encapsulation material over the phosphor.

11. The method of claim 9, wherein coating the at least one LED emitter with phosphor includes dispensing the encapsulation material dispersed with the phosphor around the at least one LED emitter.

12. The method of claim 9, wherein coating the at least one LED emitter with phosphor includes:
dispensing a first encapsulation layer around the at least one LED emitter; and
dispensing a second encapsulation layer over the first encapsulation layer,
wherein the first and second encapsulation layers include the encapsulation material, and one of the first and second encapsulation layers further includes the phosphor dispersed therein.

13. The method of claim 1, wherein the mask includes a mask substrate of a material selected from the group consisting of metal, quartz and ceramic, wherein openings formed in the mask substrate.

14. A method comprising:
die/wire bonding a plurality of LED emitters on a substrate;
forming a photoresist layer over the plurality of LED emitters;
providing a mask over the photoresist layer, the mask having an aperture over each of the plurality of LED emitters;
performing a lithography exposure to the photoresist layer through the mask;
developing the photoresist layer to expose each of the plurality of LED emitters within a respective cavity having photoresist layer walls; and
coating each of the plurality of LED emitters in each cavity with phosphor.

15. The method of claim 14, wherein coating each of the plurality of LED emitters in each cavity with phosphor includes:
dispensing a phosphor gel over the mask; and
coating each of the plurality of LED emitters with dispensed phosphor gel using the mask as a screen printing plate.

16. The method of claim 15, wherein:
the mask includes one of metal and ceramics; and
coating each of the plurality of LED emitters includes using a squeegee blade to move the phosphor gel into each cavity through the mask.

17. The method of claim 15, further comprising:
curing the phosphor gel;
removing the mask; and
removing the photoresist layer.

18. The method of claim 17, further comprising dicing the substrate.

19. A light emitting diode (LED) apparatus, comprising:
an LED emitter bonded on a substrate;
a phosphor distributed on the LED emitter; and
a polymeric wall disposed on the substrate and configured to surround the LED emitter and the phosphor, wherein the polymeric wall includes a polymeric material dispersed with filler particles.

20. The LED apparatus of claim 19, wherein the polymeric material includes a material selected from the group consisting of polyimide, polyvinylchloride, polyethylene, and polypropylene.

21. The LED apparatus of claim 19, wherein the filler particles include one of silver, aluminum, titanium oxide, and zirconium oxide.

22. The LED apparatus of claim 19, further comprising an encapsulation material disposed on the LED emitter, wherein the encapsulation material includes one of silicone and epoxy.

23. The LED apparatus of claim 22, wherein the phosphor is disposed on the LED emitter and covered by the encapsulation material.

24. The LED apparatus of claim 22, wherein
the encapsulation material includes a first encapsulation layer on the LED emitter and a second encapsulation layer on the first encapsulation layer; and
the phosphor is dispersed in one of the first and second encapsulation layers.

25. The LED apparatus of claim 23, further comprising a lens configured on the first and second encapsulation layers LED emitter.
